(19) United States
(12) Patent Application Publication
(10) Pub. No.: US 2012/0298985 A1
(43) Pub. Date: Nov. 29, 2012

(54) THIN FILM TRANSISTOR AND METHOD OF FABRICATING THE SAME

(75) Inventors: Sung Mook CHUNG, Suwon (KR); Woo-Seok Cheong, Daejeon (KR); Jaeheon Shin, Daejeon (KR); Chan Hwa Hong, Gwangyang-si (KR)

(73) Assignee: ELECTRONICS AND TELECOMMUNICATIONS RESEARCH INSTITUTE, Daejeon (KR)

(21) Appl. No.: 13/475,366

(22) Filed: May 18, 2012

(30) Foreign Application Priority Data
May 27, 2011 (KR) 10-2011-0050764

(51) Int. Cl. H01L 29/786; H01L 21/336

(52) U.S. Cl. 257/43; 438/104; 257/E29.273; 257/E21.409

(57) ABSTRACT

Provided are a thin film transistor able to increase or maximize productivity and production yield, and a method of fabricating the same. The method of fabricating the thin film transistor includes forming a gate electrode on a substrate, forming a gate insulating layer on the gate electrode, forming an active layer formed of an amorphous oxide semiconductor on the gate insulating layer, and respectively forming a source electrode and a drain electrode on both sides of the active layer above the gate electrode. The amorphous oxide semiconductor of the active layer may be doped with a metal oxide dielectric.

### CROSS-REFERENCE TO RELATED APPLICATIONS

This U.S. non-provisional patent application claims priority under 35 U.S.C. §119 of Korean Patent Application No. 10-2011-0050764, filed on May 27, 2011, the entire contents of which are hereby incorporated by reference.

### BACKGROUND

The present invention disclosed herein relates to a thin film transistor and a method of fabricating the same, and more particularly, to a thin film transistor having excellent electrical properties able to be formed by a low-temperature process and a method of fabricating the same.

Recently, research and commercialization on lightweight thin-film flat panel displays (FPDs) replacing cathode ray tubes (CRTs), typical display devices, are primarily conducted as interests in information displays grow and needs for using portable information medium increase. In particular, a liquid crystal display (LCD) among such flat panel displays is a device displaying images by using optical anisotropy of liquid crystal, which has been actively used in notebooks or desktop monitors due to its excellent resolution, color display, and image quality. The liquid crystal display is mainly composed of a color filter substrate, an array substrate, and a liquid crystal layer disposed between the color filter substrate and the array substrate. An active matrix (AM) method, which is mainly used in the liquid crystal display, is a method of driving liquid crystal of a pixel by using an amorphous silicon thin film transistor (a-Si TFT) as a switching device.

Since the liquid crystal display is not a light-emitting device but a light-receiving device, and has technical limitations in brightness, contrast ratio, and viewing angle, development of new display devices able to overcome such limitations is actively underway. Since an organic light emitting diode (OLED) as a new flat display device is a self-luminous type device, viewing angle and contrast ratio thereof are better than those of the liquid crystal display, and since back light is not required, a lightweight, thin display device may be possible and power consumption may also be low. Further, with respect to the OLED, direct-current low-voltage driving may be possible, response speed may be fast, and in particular, manufacturing costs may be low. Recently, research into a large-area organic light emitting display has been actively conducted and for this purpose, there is a need for development of a transistor having stable operation and durability by securing constant current characteristics, as a driving transistor of an organic light emitting diode.

The foregoing amorphous silicon thin film transistor used in the liquid crystal display may be fabricated by a low-temperature process, but the amorphous silicon thin film transistor may have very low mobility and may not satisfy a constant current bias condition. On the other hand, a polycrystalline silicon thin film transistor may have high mobility and a satisfactory constant current bias condition, but a large-area display may not be obtained because uniform characteristics may be difficult to obtain and a high-temperature process may be required.

### SUMMARY

The present invention provides a thin film transistor able to increase or maximize productivity and a method of fabricating the same.

The present invention also provides a thin film transistor able to increase or maximize production yield and a method of fabricating the same.

Embodiments of the present invention provide thin film transistors including: a substrate; a gate electrode disposed on the substrate; a gate insulating layer disposed on the gate electrode; an active layer disposed on the gate insulating layer and formed of an amorphous oxide semiconductor; and a source electrode and a drain electrode respectively disposed on both sides of the active layer, wherein the amorphous oxide semiconductor of the active layer may be doped with a metal oxide dielectric.

In some embodiments, the metal oxide dielectric may include at least one of tantalum oxide, tungsten oxide, or hafnium oxide.

In other embodiments, the amorphous oxide semiconductor may include indium tin oxide.

In still other embodiments, the amorphous oxide semiconductor may include indium tin oxide and tantalum oxide mixed in a ratio of about 4:1.

In even other embodiments, the thin film transistor may further include a protective layer disposed on the active layer under the source electrode and the drain electrode.

In other embodiments of the present invention, methods of fabricating a thin film transistor include: forming a gate electrode on a substrate; forming a gate insulating layer on the gate electrode; forming an active layer formed of an amorphous oxide semiconductor on the gate insulating layer; and respectively forming a source electrode and a drain electrode on both sides of the active layer above the gate electrode, wherein the amorphous oxide semiconductor may be doped with a metal oxide dielectric.

In some embodiments, the amorphous oxide semiconductor may be formed by a sputtering method or atomic layer deposition method.

In other embodiments, the sputtering method may be performed in an atmosphere having about 1% to less than about 40% of oxygen included in inert gas.

In still other embodiments, the amorphous oxide semiconductor may include indium tin oxide and the metal oxide dielectric may include at least one of tantalum oxide, tungsten oxide, or hafnium oxide, which is formed simultaneously with the indium tin oxide by the sputtering method.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a cross-sectional view illustrating a thin film transistor according to an embodiment of the present invention;

FIG. 2 is graphs showing changes in source/drain voltage between a source electrode and a drain electrode and drain current according to changes in gate voltage of a thin film transistor according to the embodiment of the present invention;

FIGS. 3 through 6 are cross-sectional views illustrating a method of fabricating a thin film transistor according to the embodiment of the present invention; and

FIG. 7 is a graph showing voltage and current of a thin film transistor according to a mixing ratio of inert gas and oxygen.

### DETAILED DESCRIPTION OF THE EMBODIMENTS

Hereinafter, preferred embodiments of the present invention will be described in more detail with reference to the accompanying drawings. Advantages and features of the present invention, and implementation methods thereof will be clarified through following embodiments described with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Further, the present invention is only defined by scopes of claims. Like reference numerals refer to like elements throughout.

In the following description, the technical terms are used only for explaining a specific exemplary embodiment while not limiting the present invention. The terms of a singular form may include plural forms unless referred to the contrary. The meaning of “comprises” and/or “comprising” specifies a property, a region, a fixed number, a step, a process, an element and/or a component but does not exclude other properties, regions, fixed numbers, steps, processes, elements and/or components. Since preferred embodiments are provided below, the order of the reference numerals given in the description is not limited thereto. Further, in the specification, it will be understood that when a layer (or film) is referred to as being ‘on’ another layer or substrate, it can be directly on the other layer or substrate, or intervening layers may also be present.

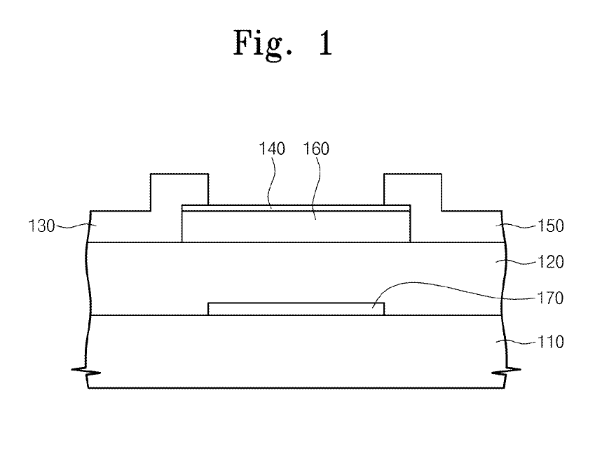

FIG. 1 is a cross-sectional view illustrating a thin film transistor according to an embodiment of the present invention.

Referring to FIG. 1, a transistor of the present invention may include an active layer 160 formed of an amorphous oxide semiconductor disposed above a gate electrode 170 between a source electrode 130 and a drain electrode 150. The active layer 160 may form a channel, in which electrons or holes are transferred between the source electrode 130 and the drain electrode 150 by means of a gate voltage applied to the gate electrode 170. The amorphous oxide semiconductor of the active layer 160 may include indium tin oxide doped with a metal oxide dielectric, such as tantalum oxide, tungsten oxide, and hafnium oxide. For example, a mixing ratio between indium tin oxide and tantalum oxide may be about 4:1. The amorphous oxide semiconductor may have an electron mobility of about 10 cm²/Vs or more higher than that of amorphous silicon. The indium tin oxide doped with the metal oxide dielectric may have higher transparency than that of amorphous silicon or polycrystalline silicon. A protective layer 140 may be disposed on the active layer 160. The protective layer 140 may include at least one of aluminum oxide, silicon oxide, or silicon nitride.

The source electrode 130 and the drain electrode 150 may be disposed on both sides of the active layer 160, respectively. The source electrode 130 and the drain electrode 150 may include transparent metal oxides formed of combinations of one or more selected from the group consisting of indium tin oxide (ITO), gallium zinc oxide (GZO), indium gallium zinc oxide (IGZO), indium gallium oxide (IGO), indium zinc oxide (IZO), and indium oxide (In₂O₃).

The gate electrode 170 may be insulated from the active layer 160 by means of a gate insulating layer 120. For example, the gate electrode 170 may include one of transparent metal oxides formed of combinations of one or more selected from the group consisting of ITO, GZO, IGZO, IGO, IZO, and In₂O₃, and conductive metals, such as tungsten, aluminum, and copper. A substrate 110 may include silicon, glass, and plastic.

The gate insulating layer 120 may include an insulating dielectric or metal oxide dielectric formed of a combination of one or more selected from the group consisting of aluminum oxide (Al₂O₃), silicon oxide (SiO₂), silicon nitride (SiNₓ), zirconium oxide (ZrO₂), hafnium oxide (HfO₂), titanium oxide (TiO₂), tantalum oxide (Ta₂O₅), a barium-strontium-titanium-oxygen (Ba—Sr—Ti—O) compound, and a bismuth-zinc-niobium-oxygen (Bi—Zn—Nb—O) compound.

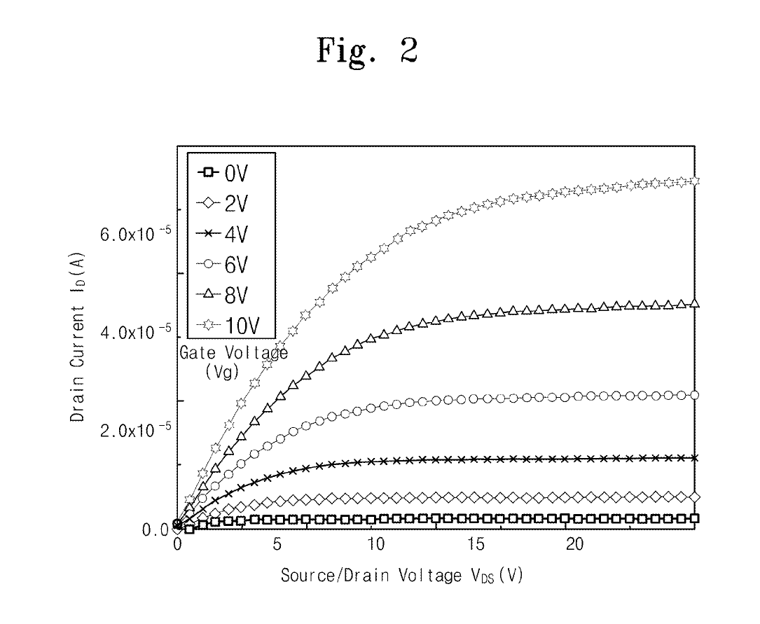

FIG. 2 is graphs showing changes in source/drain voltage between a source electrode and a drain electrode and drain current according to changes in gate voltage of a thin film transistor according to the embodiment of the present invention.

Referring to FIGS. 1 and 2, when a gate voltage (V_{g}) applied to the gate electrode 170 increases, a drain current (I_{D}) of the transistor of the present invention may increase according to a source/drain voltage (V_{DS}) between the source electrode 130 and the drain electrode 150. Herein, the axis of abscissas denotes an amount of the source/drain voltage and the axis of ordinates denotes an amount of current density. When about 5 V of the source/drain voltage and about 6 V to about 10 V of the gate voltage are applied, the source/drain voltage and the drain current may increase with constant slopes. The amorphous oxide semiconductor may have better electrical properties than those of amorphous silicon.

Therefore, the thin film transistor according to the embodiment of the present invention may increase or maximize productivity. Shape of each element illustrated in FIG. 1 is exemplified and FIG. 1 disclosed a bottom gate- or stacked-type thin film transistor in which the gate electrode 170 is disposed under the active layer 160. However, the embodiment of the present invention may include a top gate- or reverse stacked-type thin film transistor in which the gate electrode 170 is disposed above the active layer 160.

A method of fabricating a thin film transistor according to the present invention having the foregoing configuration is described below.

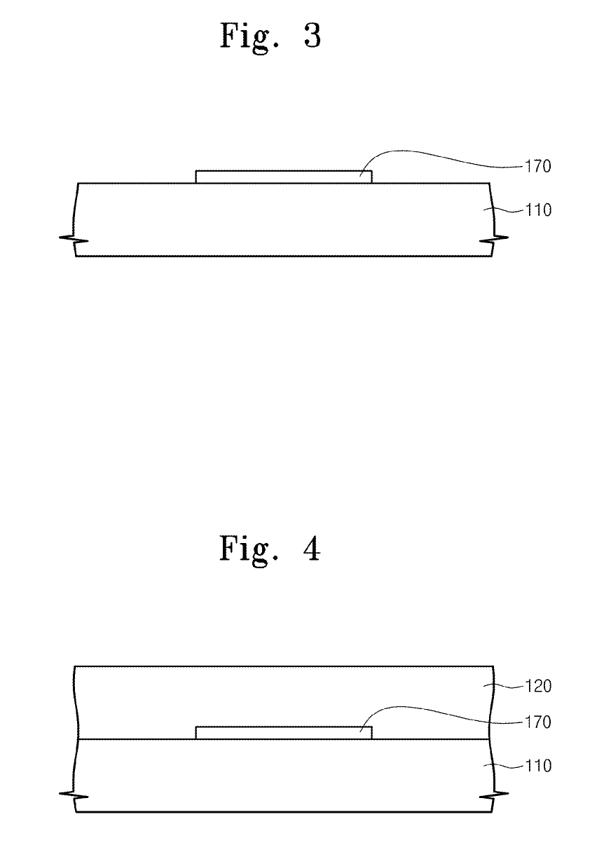

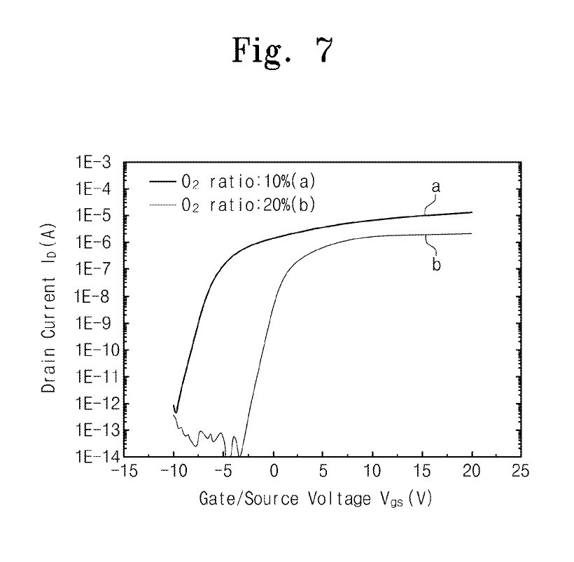

FIGS. 3 through 6 are cross-sectional views illustrating a method of fabricating a thin film transistor according to the embodiment of the present invention, and FIG. 7 is a graph showing voltage and current of a thin film transistor according to a mixing ratio of inert gas and oxygen.

Referring to FIG. 3, a gate electrode 170 is disposed on a substrate 110. The gate electrode 170 may be formed by performing a photolithography process or lift-off process on a conductive metal deposited on the substrate 110.

Referring to FIG. 4, a gate insulating layer 120 covering the gate electrode 170 is disposed. The gate insulating layer 120 may be formed by using an atomic layer deposition (ALD), chemical vapor deposition (CVD), or sputtering method.

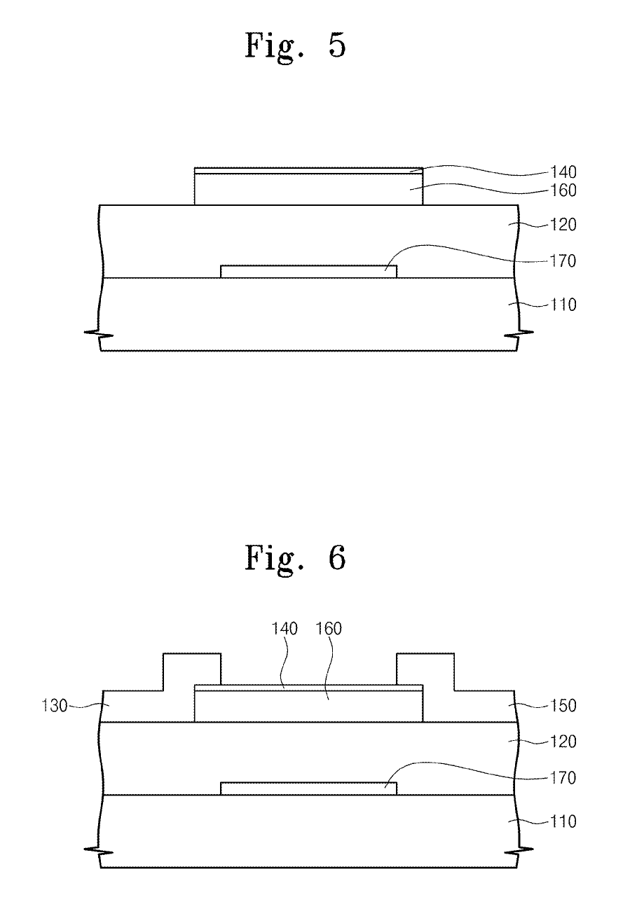

Referring to FIGS. 1 and 5, an active layer 160 and a protective layer 140 are disposed on the gate insulating layer 120 on the gate electrode 170. The active layer 160 may include an amorphous oxide semiconductor. The protective layer 140 may include aluminum oxide, silicon oxide, or silicon nitride, which is formed by a sputtering process or rapid thermal process. The amorphous oxide semiconductor of the active layer 160 may include indium tin oxide doped with a metal oxide dielectric. The active layer 160 and the protective layer 140 may be patterned by a photolithography process. The active layer 160 may be formed by a low-temperature deposition process, such as a sputtering method or atomic layer deposition method performed at about 300° C. or less. The low-temperature deposition process may minimize contamination of the active layer 160 from impurities diffused from the substrate 110.

Therefore, the method of fabricating a thin film transistor according to the embodiment of the present invention may increase or maximize production yield.

For example, the sputtering method is a method of forming a thin film formed of metal particles, which are generated from a metal target bombarded by charged inert gas, on the substrate 110. The metal target may include an indium plate, a tin plate, and a tantalum plate. Also, the metal target may include a tungsten plate or hafnium plate instead of the tantalum plate. The inert gas may be charged by high-frequency power. The high-frequency power may include energy ranging from about 30 W to about 50 W. At this time, an amorphous oxide semiconductor may be formed, in which a mixing ratio between indium tin oxide and tantalum oxide is about 4:1. The amorphous oxide semiconductor may be formed in an atmosphere in which inert gas and oxygen are mixed.

Referring to FIG. 6, a source electrode 130 and a drain electrode 150 are disposed on both sides of the active layer 160. The source electrode 130 and the drain electrode 150 may be formed by performing a photolithography process or lift-off process on a conductive metal deposited on the active layer 160 and the gate insulating layer 120.

Referring to FIGS. 1 to 7, when about 10% of oxygen is mixed with inert gas, a drain current (I_{D}) between the source electrode 130 and the drain electrode 150 may be saturated at about 10⁻⁵ A according to changes in a voltage (Vgs) between the gate electrode 170 and the source electrode 130 ranging from about −10 V to about 20 V (see FIG. 7(a)). When about 20% of oxygen is mixed with inert gas, a drain current between the source electrode 130 and the drain electrode 150 may be saturated at about 10⁻⁶ A (see FIG. 7(b)). The larger the mixing ratio of oxygen to inert gas is, the lower the drain current of the amorphous oxide semiconductor may be. Oxygen may be mixed with inert gas in an amount range of about 1% to less than about 40%. As described above, the amorphous oxide semiconductor may include an insulating metal oxide dielectric, such as tantalum oxide, tungsten oxide, and hafnium oxide, and transparent conductive indium tin oxide. The amorphous oxide semiconductor may be formed on the substrate 110 of a plastic material by a low-temperature sputtering method. Also, the amorphous oxide semiconductor may be evenly deposited on a large-area substrate 110. Although not shown in the drawings, the amorphous oxide semiconductor may be annealed at a temperature of about 200° C. or more. Therefore, the method of fabricating a thin film transistor according to the embodiment of the present invention may increase or maximize production yield.

According to the embodiment of the present invention, an active layer may include an amorphous oxide semiconductor. The amorphous oxide semiconductor may include indium tin oxide doped with a metal oxide dielectric. The amorphous oxide semiconductor may have mobility and constant current characteristics better than those of amorphous silicon. Also, the amorphous oxide semiconductor may be formed by a low-temperature process at a temperature of about 300° C., which is lower than that of polycrystalline silicon. Therefore, a thin film transistor of the present invention and a fabricating method thereof may increase or maximize productivity and production yield.

While preferred embodiments of the present invention has been particularly shown and described with reference to the accompanying drawings, it will be understood by those skilled in the art that various changes in form and details may be made therein without departing from the spirit and scope of the invention as defined by the appended claims. Therefore, the preferred embodiments should be considered in descriptive sense only and not for purposes of limitation.

What is claimed is:

1. A thin film transistor comprising:
a substrate;
a gate electrode disposed on the substrate;
a gate insulating layer disposed on the gate electrode;
an active layer disposed on the gate insulating layer and formed of an amorphous oxide semiconductor; and
a source electrode and a drain electrode respectively disposed on both sides of the active layer,
wherein the amorphous oxide semiconductor of the active layer is doped with a metal oxide dielectric.

2. The thin film transistor of claim 1, wherein the metal oxide dielectric comprises at least one of tantalum oxide, tungsten oxide, or hafnium oxide.

3. The thin film transistor of claim 2, wherein the amorphous oxide semiconductor comprises indium tin oxide.

4. The thin film transistor of claim 3, wherein the amorphous oxide semiconductor comprises indium tin oxide and tantalum oxide mixed in a ratio of about 4:1.

5. The thin film transistor of claim 1, further comprising a protective layer disposed on the active layer under the source electrode and the drain electrode.

6. A method of fabricating a thin film transistor, the method comprising:
forming a gate electrode on a substrate;
forming a gate insulating layer on the gate electrode;
forming an active layer formed of an amorphous oxide semiconductor on the gate insulating layer; and
respectively forming a source electrode and a drain electrode on both sides of the active layer above the gate electrode,
wherein the amorphous oxide semiconductor is doped with a metal oxide dielectric.

7. The method of claim 6, wherein the amorphous oxide semiconductor is formed by a sputtering method or atomic layer deposition method.

8. The method of claim 7, wherein the sputtering method is performed in an atmosphere having about 1% to less than about 40% of oxygen included in inert gas.

9. The method of claim 8, wherein the amorphous oxide semiconductor comprises indium tin oxide and the metal oxide dielectric comprises at least one of tantalum oxide, tungsten oxide, or hafnium oxide, which is formed simultaneously with the indium tin oxide by the sputtering method.
